(19) United States
(12) Patent Application Publication
(10) Pub. No.: US 2015/0207031 A1
(43) Pub. Date: Jul. 23, 2015

(54) SEMICONDUCTOR LIGHT EMITTING STRUCTURE

(71) Applicant: Lextar Electronics Corporation, Hsinchu (TW)

(72) Inventor: Po-Hung Tsou, New Taipei City (TW)

(21) Appl. No.: 14/303,653

(22) Filed: Jun. 13, 2014

(30) Foreign Application Priority Data
Jan. 23, 2014 (TW) 103102452

(51) Int. Cl. H01L 33/22; H01L 33/42; H01L 33/24

(52) U.S. Cl. CPC H01L 33/22; H01L 33/24; H01L 33/42

(57) ABSTRACT

A semiconductor light emitting structure is provided. The semiconductor light emitting structure comprises a substrate, a first semiconductor layer, an active layer and a second semiconductor layer. The first semiconductor layer is formed on the substrate. The active layer is formed on a portion of the first semiconductor layer, and the other portion of the first semiconductor layer is exposed and used as a first electrode predetermined area. The second semiconductor layer is formed on the active layer. The second semiconductor layer has a second electrode predetermined area and a micro-structure predetermined area disposed thereon. The micro-structure predetermined area comprises a plurality of concaves and a plurality of protrusions, and each protrusion is correspondingly located within one of the concaves.

This application claims the benefit of Taiwan application Serial No. 103102452, filed Jan. 23, 2014, the subject matter of which is incorporated herein by reference.

### BACKGROUND OF THE INVENTION

1. Field of the Invention

The invention relates in general to a semiconductor light emitting structure, and more particularly to a semiconductor light emitting structure capable of increasing light extraction efficiency.

2. Description of the Related Art

The light-emitting diode (LED) emits a light by converting electric energy into photo energy. The LED is mainly composed of semiconductors. Of the semiconductors, those having a larger ratio of holes carrying positive electricity are referred as P type semiconductors, and those having a larger ratio of electrons carrying negative electricity are referred as N type semiconductors. The joint connecting a P type semiconductor and an N type semiconductor forms a PN joint. When a voltage is applied to the positive and negative electrodes of an LED chip, the electrons and the holes will be combined and then emit energy in a form of light.

Since the semiconductor layer of LED has a refractive index very different from that of the air, the light emitted towards the surface of the semiconductor can be easily reflected back and has a very small output angle. Therefore, a portion of the light is contained within the substrate and cannot be fully extracted, and the light extraction efficiency will deteriorate.

### SUMMARY OF THE INVENTION

The invention is directed to a semiconductor light emitting structure capable of increasing light extraction efficiency.

According to one embodiment of the present invention, a semiconductor light emitting structure is provided. The semiconductor light emitting structure comprises a substrate, a first semiconductor layer, an active layer and a second semiconductor layer. The first semiconductor layer is formed on the substrate. The active layer is formed on a portion of the first semiconductor layer, and the other portion of the first semiconductor layer is exposed and used as a first electrode predetermined area. The second semiconductor layer is formed on the active layer, the second semiconductor layer has a second electrode predetermined area and a micro-structure predetermined area disposed thereon. The micro-structure predetermined area comprises a plurality of concaves and a plurality of protrusions, and each protrusion is correspondingly located within one of the concaves.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A and 1B respectively are a top view of a transparent conductive layer having a reticular distribution of openings and formed on a surface of a semiconductor layer and a cross-sectional view of a regional area A.

FIG. 1C is a schematic diagram of a protrusion formed on a surface of a semiconductor layer.

FIG. 2A is a schematic diagram of a semiconductor light emitting structure according to an embodiment of the invention.

FIGS. 2B and 2C are different implementations of concaves and protrusions.

FIG. 3 is a schematic diagram of a semiconductor light emitting structure according to an embodiment of the invention.

FIG. 4 is a schematic diagram of a semiconductor light emitting structure according to an embodiment of the invention.

FIGS. 5A and 5B respectively are a schematic diagram of a semiconductor light emitting structure according to an embodiment of the invention and a schematic diagram of another implementation.

### DETAILED DESCRIPTION OF THE INVENTION

According to a semiconductor light emitting structure disclosed in an exemplary embodiment of the present embodiment, a plurality of concaves and protrusions are formed in a micro-structure predetermined area with each protrusion being correspondingly located within one of the concaves. Conventional semiconductor layer has a smooth surface which may easily form a full reflective surface. In comparison to the conventional semiconductor layer, the concaves and protrusions are formed on the surface of the semiconductor layer to change the profile of the surface, so that the surface will not form a full reflective surface and the light extraction efficiency can be increased.

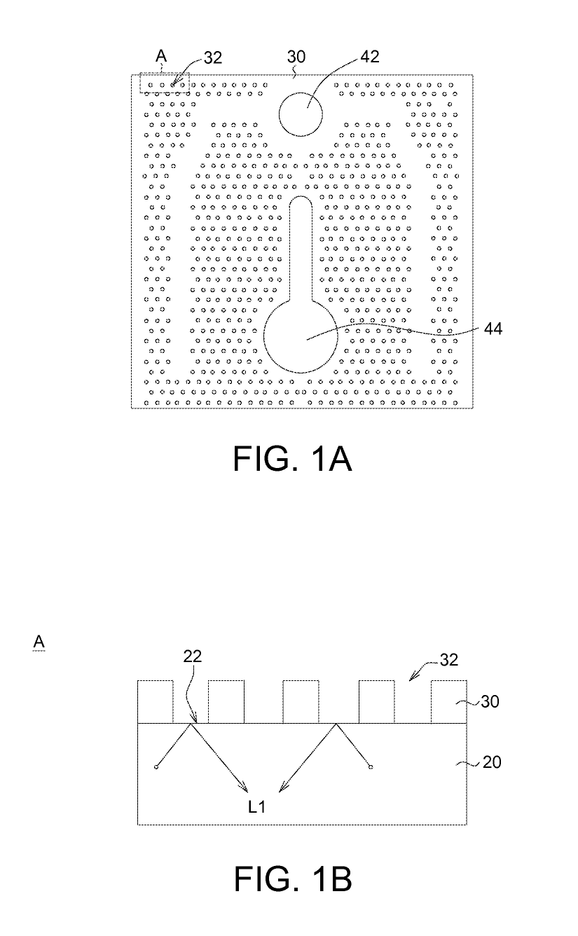

Please refer to FIGS. 1A and 1B. FIG. 1A is a top view of a transparent conductive layer 30 having a reticular distribution of openings 32 formed on a surface 22 of a semiconductor layer 20. FIG. 1B is a cross-sectional view of a regional area A in FIG. 1A. As indicated in FIG. 1A, the transparent conductive layer 30 has a reticular distribution of openings 32 disposed thereon except the areas in which electrodes 42 and 44 are located. Each opening 32 has a size of 3˜10 micrometers (μm). As indicated in FIG. 1B, the reticular distribution of openings 32 is for increasing the light extraction efficiency. Since the surface 22 on which the openings are formed is a smooth surface, the light L1 may easily be fully reflected by the surface 22 due to a large difference between the coefficients of refraction of the semiconductor layer 20 and that of the air, so that the light extraction efficiency cannot be effectively increased. Therefore, the transparent conductive layer 30 having a reticular distribution of openings 32 alone cannot increase the light extraction efficiency.

Referring to FIG. 1C, a schematic diagram of a protrusion 24 formed on a surface 22 of a semiconductor layer 20 is shown. The protrusion 24 is, for example, a cylinder, and the top surface of the cylinder is, for example, a dome surface, so that most of the light L2 can be emitted outwards through the surface of the protrusion 24. In the present application, the protrusion 24 is used to change the profile of the surface so that the surface 22 of the semiconductor layer 20 will not form a full reflective surface and the light extraction efficiency can be increased.

A number of embodiments are disclosed below for elaborating the invention. However, the embodiments of the invention are exemplary and explanatory only, not for limiting the scope of protection of the invention.

### First Embodiment

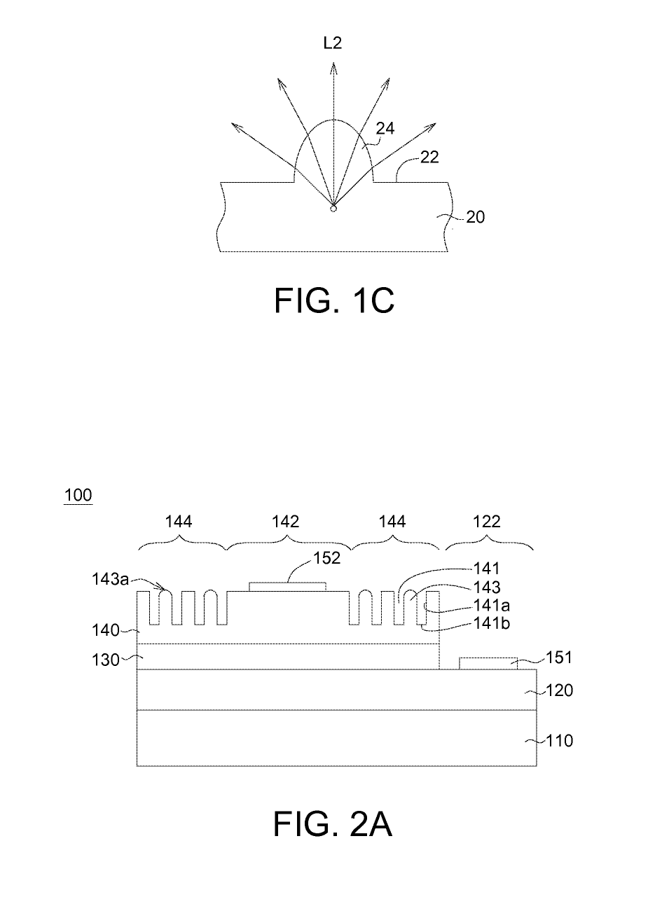

Referring to FIG. 2A, a schematic diagram of a semiconductor light emitting structure 100 according to an embodiment of the invention is shown. The semiconductor light emitting structure 100 comprises a substrate 110, a first semiconductor layer 120, an active layer 130, a second semiconductor layer 140, a first electrode 151 and a second electrode 152. The first semiconductor layer 120 is formed on the substrate 110. In an embodiment, the substrate 110 is, for example, a sapphire substrate or a silicon substrate, and the first semiconductor layer 120 can be directly formed on the substrate 110 or indirectly formed on the substrate 110, for example, through a buffer layer (not illustrated).

The active layer 130 is formed on a portion of the first semiconductor layer 120, and the other portion of the first semiconductor layer 120 is exposed and used as a first electrode predetermined area 122. The first electrode predetermined area 122 is an area by which the first electrode 151 contacts the first semiconductor layer 120. Besides, the second semiconductor layer 140 is formed on the active layer 130, and the second semiconductor layer 140 has a second electrode predetermined area 142 and a micro-structure predetermined area 144 disposed thereon. The second electrode predetermined area 142 is an area by which the second electrode 152 contacts the second semiconductor layer 140.

In an embodiment, the first semiconductor layer 120 is an N-type semiconductor layer, and the second semiconductor layer 140 is a P-type semiconductor layer. Or, the first semiconductor layer 120 is a P-type semiconductor layer, and the second semiconductor layer 140 is an N-type semiconductor layer. When the first semiconductor layer 120 and the second semiconductor layer 140 having opposite electricity are electrified, electrons and holes which move towards the active layer 130 from the first electrode 151 and the second electrode 152 respectively are combined to illuminate.

The first semiconductor layer 120, the active layer 130 and the second semiconductor layer 140 are formed by a nitride composed of elements from group IIIA of the periodic table. For instance, the first semiconductor layer 120, the active layer 130 and the second semiconductor layer 140 are formed by a material selected from one or a combination of the groups composed of gallium nitride (GaN), indium gallium nitride (InGaN), aluminum gallium nitride (AlGaN) or aluminum indium gallium nitride (AlInGaN).

As indicated in FIG. 2A, the micro-structure predetermined area 144 comprises a plurality of concaves 141 and many protrusions 143, and each protrusion 143 is correspondingly located within one of the concaves 141. In an embodiment, the concaves 141 form a reticular distribution in the micro-structure predetermined area 144, not the second electrode predetermined area 142. The quantity of concaves 141 is not limited, and each protrusion 143 is correspondingly located within one of the concaves 141. That is, each concave 141 has a protrusion 143 disposed in the center, and the protrusion 143 is surrounded by a circular concave.

The protrusions 143 and the concaves 141, such as micro-structures formed by way of dry etching or wet etching, change the profile of the surface of the second semiconductor layer 140, such that the surface of the second semiconductor layer 140 will not form a full reflective surface and the light extraction efficiency can be increased.

As indicated in FIG. 2A, each concave 141 has a sidewall 141a and a bottom surface 141b, and each protrusion 143 is vertically projected from the bottom surface 141b of a concave 141 without contacting the sidewall 141a of the concave 141. The protrusion 143 is surrounded within the concave 141, and the size of the concave 141 is larger than that of the protrusion 143. In an embodiment, the concave 141 has a size of 3˜10 μm, and the size of the protrusion 143 is adjusted according to the size of the concave 141. For example, the protrusion 143 has a size of 1˜5 μm. Moreover, the top surface 143a of the protrusion 143 is a curved surface through which most of the light is emitted outwards.

FIGS. 2B and 2C are different implementations of concaves 141 and protrusions 143. The differences between FIGS. 2A, 2B and 2C are elaborated below. As indicated in FIG. 2A, the concave 141 penetrates a portion of the second semiconductor layer 140. That is, the depth of the concave 141 is smaller than the thickness of the second semiconductor layer 140. As indicated in FIG. 2B, the concave 141 penetrates the second semiconductor layer 140 and a portion of the active layer 130. That is, the depth of the concave 141 is larger than the thickness of the second semiconductor layer 140 but smaller than the total thickness of the second semiconductor layer 140 and the active layer 130. As indicated in FIG. 2C, the concave 141 penetrates the second semiconductor layer 140, the active layer 130 and a portion of the first semiconductor layer 120. That is, the depth of the concave 141 is larger than the total thickness of the second semiconductor layer 140 and the active layer 130 but smaller than the total thickness of the second semiconductor layer 140, the active layer 130 and the first semiconductor layer 120.

In the above embodiments, although the depth of the concave 141 is basically equal to the height (or depth) of the protrusion 143, the invention is not limited thereto. In an embodiment, the depth of the concave 141 can be larger than the height of the protrusion 143. In another embodiment, the depth of the concave 141 can be smaller than the height of the protrusion 143. The above variations are based on actual needs.

### Second Embodiment

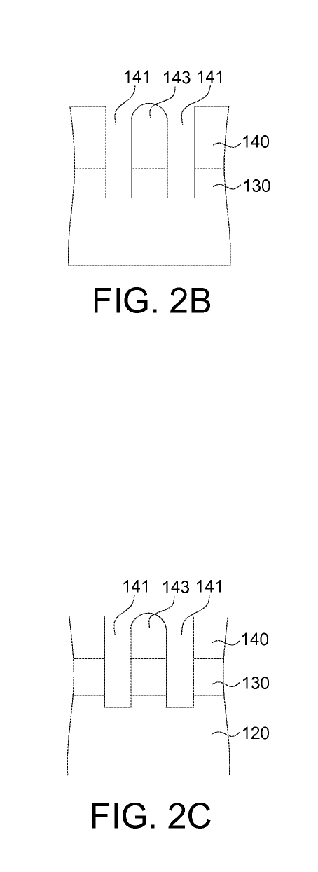

Referring to FIG. 3, a schematic diagram of a semiconductor light emitting structure 101 according to an embodiment of the invention is shown. The semiconductor light emitting structure 101 of the present embodiment is different from that of the first embodiment in that a conductive layer 153 is disposed on the second semiconductor layer 140. The second electrode 152 is disposed on the conductive layer 153. The conductive layer 153 is, for example, a transparent conductive layer 153, which covers almost the entire second semiconductor layer 140 except the concaves 141 and the protrusions 143.

The conductive layer 153 has many openings 154 as illustrated in FIG. 1A. The openings 154 penetrate the conductive layer 153, and each opening 154 corresponds to one of the concaves 141. Since the surface corresponding to the openings 154 is not smooth, the light will not be totally reflected due to a large difference between the coefficient of refraction of the second semiconductor layer 140 and that of the air. Therefore, the semiconductor light emitting structure 101 of the present embodiment effectively increases the light extraction efficiency.

In an embodiment, the conductive layer 153 can be formed by a transparent material such as indium tin oxide (ITO) or indium zinc oxide (IZO) without affecting the light outputting area. Meanwhile, under the current is guided by the conductive layer 153, the second electrode 152 does not need to be large-sized and the area of the second electrode 152 can be relatively decreased. Thus, the light outputting area blocked by the second electrode 152 becomes smaller and the design needs can thus be satisfied.

### Third Embodiment

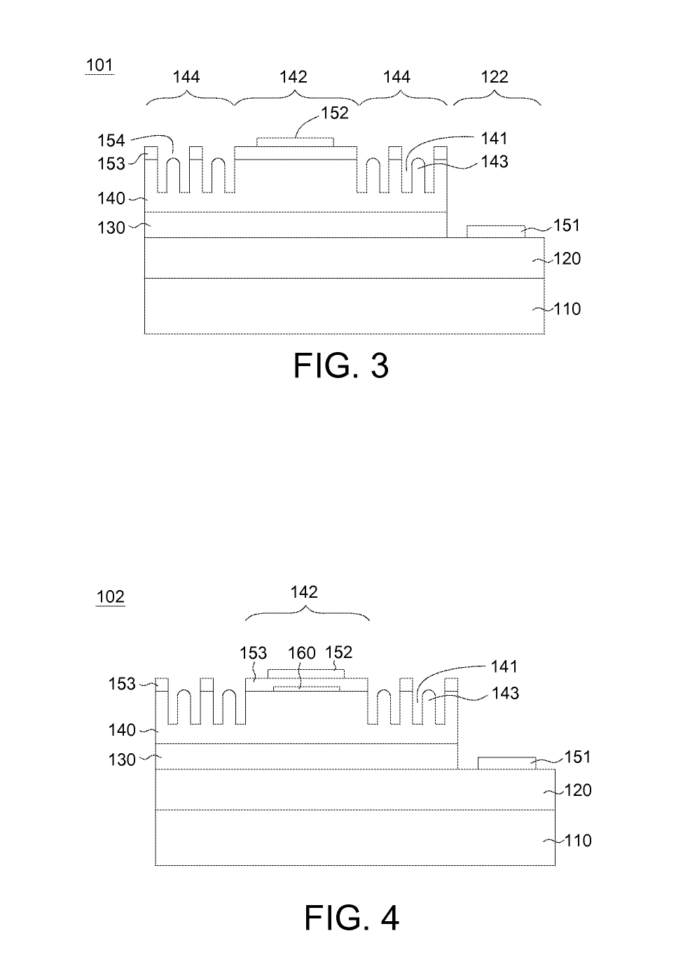

Referring to FIG. 4, a schematic diagram of a semiconductor light emitting structure 102 according to an embodiment of the invention is shown. The semiconductor light emitting structure 102 of the present embodiment is different from that of the second embodiment in that the second electrode predetermined area 142 has a current blocking layer 160 disposed thereon and covered by the conductive layer 153. The current blocking layer 160 is located on the second semiconductor layer 140 and the position of the current blocking layer 160 is opposite to that of the second electrode 152, so that the current can be uniformly diffused in the conductive layer 153, and the current crowding effect which occurs under the second electrode 152 can be mitigated during large current is injected into the second electrode 152.

In an embodiment, the current blocking layer 160, for example, formed by an AlGaN semiconductor material with high energy gap, can be doped with an N-type dopant. The current blocking layer 160 blocks the current moving downwards from the second electrode 152 and makes the current move towards the peripheral of the current blocking layer 160, so that the current is injected to the second semiconductor layer 140 through the peripheral of the conductive layer 153, and the current diffusion effect can thus be increased.

### Fourth Embodiment

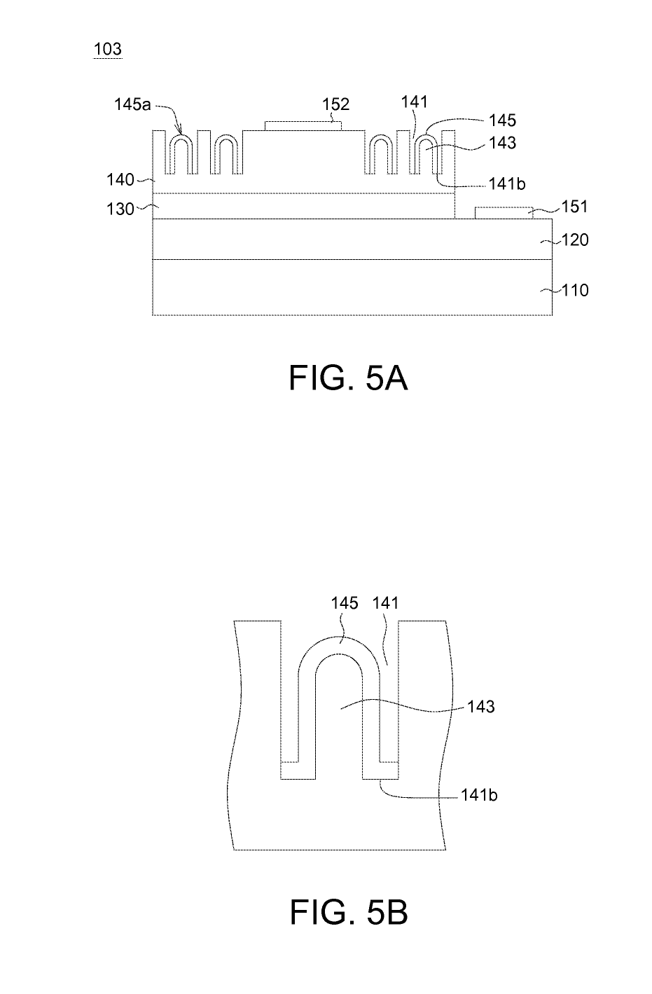

FIGS. 5A and 5B respectively are a schematic diagram of a semiconductor light emitting structure 103 according to an embodiment of the invention and a schematic diagram of another implementation. The semiconductor light emitting structure 103 of the present embodiment is different from that of the first embodiment in that the protrusions 143 are covered by an insulating material layer 145. As indicated in FIG. 5B, the insulating material layer 145 can further cover the bottom surface 141b of the concave 141.

In an embodiment, the insulating material layer 145, made of an oxide, a nitride or a nitrogen oxide, can be formed on the protrusions 143 by way of physical vapor deposition, so that the insulating material layer 145 and the protrusion 143 form a conformal structure. Thus, the top surface 145a of the insulating material layer 145 can maintain a dome surface to increase the light extraction efficiency.

The refractive index of the insulating material layer 145 is between the refractive index of the air and the refractive index of the second semiconductor layer 140. For example, the refractive index of the insulating material layer 145 is between 1˜2.5 such that the light will not be fully reflected due to the large difference between the coefficient of refraction of the second semiconductor layer 140 and that of the air. Preferably, the refractive index of the insulating material layer 145 is between 1.3˜2. Also, the insulating material layer 145 can be single- or multi-layered, and the invention is not limited thereto.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor light emitting structure, comprising:
a substrate;
a first semiconductor layer formed on the substrate;
an active layer formed on a portion of the first semiconductor layer, wherein the other portion of the first semiconductor layer is exposed and used as a first electrode predetermined area; and
a second semiconductor layer formed on the active layer, wherein the second semiconductor layer has a second electrode predetermined area and a micro-structure predetermined area disposed thereon, the micro-structure predetermined area comprises a plurality of concaves and a plurality of protrusions, and each protrusion is correspondingly located within one of the concaves.

2. The semiconductor light emitting structure according to claim 1, wherein each concave has a sidewall and a bottom surface.

3. The semiconductor light emitting structure according to claim 2, wherein each concave penetrates a portion of the second semiconductor layer, or penetrates the second semiconductor layer and a portion of the active layer, or penetrates the second semiconductor layer, the active layer and a portion of the first semiconductor layer.

4. The semiconductor light emitting structure according to claim 3, wherein each protrusion is vertically projected from the bottom surface of one of the concaves but does not contact the sidewall of the concave.

5. The semiconductor light emitting structure according to claim 4, wherein each protrusion has a top surface being a curved surface.

6. The semiconductor light emitting structure according to claim 5, further comprising a conductive layer disposed on the second semiconductor layer, wherein the conductive layer has a plurality of openings each penetrating the conductive layer, and the positions of the openings correspond to the positions of the concaves.

7. The semiconductor light emitting structure according to claim 6, wherein the conductive layer is a transparent conductive layer.

8. The semiconductor light emitting structure according to claim 7, further comprising a current blocking layer disposed on the second semiconductor layer and located in the second electrode predetermined area and covered by the conductive layer.

9. The semiconductor light emitting structure according to claim 1, wherein on the first electrode predetermined area further comprises a first electrode, and on the second electrode predetermined area further comprises a second electrode.

10. The semiconductor light emitting structure according to claim 1, further comprising an insulating material layer covering the protrusions.

11. The semiconductor light emitting structure according to claim 10, wherein the insulating material layer further covers a bottom surface of each concave.

12. The semiconductor light emitting structure according to claim 11, wherein the insulating material layer has a refractive index between 1˜2.5.

13. The semiconductor light emitting structure according to claim 12, wherein the insulating material layer has a refractive index between 1.3˜2.
